(19) United States
(12) Patent Application Publication
(10) Pub. No.: US 2023/0236261 A1
(43) Pub. Date: Jul. 27, 2023

(54) METHOD AND DEVICE FOR ACQUIRING BATTERY CAPACITY, STORAGE MEDIUM, AND SERVER

(71) Applicant: BYD COMPANY LIMITED, Shenzhen (CN)

(72) Inventors: Yubo LIAN, Shenzhen (CN); Heping LING, Shenzhen (CN); Siliang CHEN, Shenzhen (CN); Zhengzheng WANG, Shenzhen (CN); Junzi LI, Shenzhen (CN)

(21) Appl. No.: 18/128,703

(22) Filed: Mar. 30, 2023

Related U.S. Application Data
(63) Continuation of application No. PCT/CN2021/119637, filed on Sep. 22, 2021.

(30) Foreign Application Priority Data
Sep. 30, 2020 (CN) 202011066177.3

(51) Int. Cl. G01R 31/392; G01R 31/367; G01R 31/387

(52) U.S. Cl. CPC G01R 31/392; G01R 31/367; G01R 31/387

(57) ABSTRACT

A method for acquiring a battery capacity, includes: acquiring multiple initial charging parameters of a battery when the battery is charged during a current charging process, where state of charge (SOC) of the battery in the current charging process changes for a range covering an SOC range, or a minimum charging temperature of the battery in the current charging process is greater than or equal to a temperature threshold; periodically acquiring multiple actual charging parameters of the battery during the current charging process and a current number of charging times corresponding to the current charging process; and acquiring, according to the multiple initial charging parameters, the multiple actual charging parameters, and the current number of charging times, a predicted battery capacity of the battery in a next charging process.

### CROSS-REFERENCE TO RELATED APPLICATIONS

This application is a Continuation application of International Patent Application No. PCT/CN2021/119637, filed on Sep. 22, 2021, which is based on and claims priority to and benefits of Chinese Patent Application No. 202011066177.3 filed on Sep. 30, 2020. The entire content of all of the above-referenced application is incorporated herein by reference.

### FIELD

The present disclosure relates to the technical field of batteries, and specifically to a method and a device for acquiring a battery capacity, a storage medium, and a server.

### BACKGROUND

Electric vehicles are motor vehicles completely or partially powered by power batteries. The battery capacity of a power battery is an important factor affecting the performance of electric vehicles, and the accurate estimation of the battery capacity can improve the estimation accuracy of state of charge (SOC), the prediction accuracy of the peak power and the estimation accuracy of a cruising range. Therefore, in a battery management system, the battery capacity is often used as an important indicator charactering the battery health.

In the related art, the battery capacity of a battery can be calculated according to the charging and discharging current of a battery pack. However, this method requires the detection of an open circuit voltage (OCV) and OCV can be obtained only after charging and discharging with a small current and fully standing. The acquisition time is long, causing a low efficiency in the estimation of the battery capacity.

### SUMMARY

To solve the above problems, the present disclosure provides a method and a device for acquiring a battery capacity, a storage medium, and a server.

In a first aspect, the present disclosure provides a method for acquiring a battery capacity, which includes: acquiring multiple initial charging parameters of a battery when the battery is charged during a current charging process, where state of charge (SOC) of the battery in the current charging process changes for a range covering an SOC range, or a minimum charging temperature of the battery in the current charging process is greater than or equal to a temperature threshold; periodically acquiring multiple actual charging parameters of the battery during the current charging process and a current number of charging times corresponding to the current charging process; and acquiring, according to the multiple initial charging parameters, the multiple actual charging parameters, and the current number of charging times, a predicted battery capacity of the battery in a next charging process.

In an embodiment, the step of acquiring, according to the multiple initial charging parameters, the multiple actual charging parameters and the current number of charging times, a predicted battery capacity of the battery in a next charging process includes estimating, according to the multiple initial charging parameters and the multiple actual charging parameters, a current maximum usable capacity of the battery; acquiring, according to the current maximum usable capacity and the current number of charging times, a capacity correlation, where the capacity correlation includes a correspondence between the predicted battery capacity and the number of charging times; and acquiring, according to the capacity correlation, the predicted battery capacity of the battery in the next charging process.

In an embodiment, the step of estimating, according to the multiple initial charging parameters and the multiple actual charging parameters, a current maximum usable capacity of the battery includes: acquiring, according to the multiple initial charging parameters, an initial capacity increment profile; acquiring, according to the multiple actual charging parameters, an actual capacity increment profile; and estimating, according to the initial capacity increment profile and the actual capacity increment profile, the current maximum usable capacity of the battery.

In an embodiment, the step of estimating, according to the initial capacity increment profile and the actual capacity increment profile, the current maximum usable capacity of the battery includes: acquiring first initial position information corresponding to a second initial peak value and second initial position information corresponding to a third initial peak value on the initial capacity increment profile; acquiring first current position information corresponding to a second actual peak value and second current position information corresponding to a third actual peak value on the actual capacity increment profile; and estimating, according to the first initial position information, the second initial position information, the first current position information, the second current position information, the multiple initial charging parameters, and the multiple actual charging parameters, the current maximum usable capacity of the battery.

In an embodiment, the step of acquiring, according to the capacity correlation, the predicted battery capacity of the battery in the next charging process includes acquiring a target number of charging times corresponding to the next charging process; and acquiring, according to the target number of charging times and the capacity correlation, the predicted battery capacity of the battery in the next charging process.

In an embodiment, before the step of acquiring, according to the current maximum usable capacity and the current number of charging times, a capacity correlation, the method further includes: acquiring a historical maximum usable capacity in historical charging processes before the current charging process and a historical number of charging times corresponding to the historical maximum usable capacity. The step of acquiring, according to the current maximum usable capacity and the current number of charging times, a capacity correlation includes: acquiring, according to the current maximum usable capacity, the current number of charging times, the historical maximum usable capacity and the historical number of charging times, the capacity correlation.

In a second aspect, the present disclosure provides a device for acquiring a battery capacity, which includes: an initial parameter acquisition module, configured to acquire multiple initial charging parameters of a battery when the battery is charged during a current charging process, where state of charge (SOC) of the battery in the current charging process changes for a range covering an SOC range, or a minimum charging temperature of the battery in the current charging process is greater than or equal to a temperature threshold; an actual parameter acquisition module, configured to periodically acquire multiple actual charging parameters of the battery during the current charging process and a current number of charging times corresponding to the current charging process; and a battery capacity acquisition module, configured to acquire, according to the multiple initial charging parameters, the multiple actual charging parameters and the current number of charging times, a predicted battery capacity of the battery in a next charging process.

In an embodiment, the battery capacity acquisition module is further configured to: estimate, according to the multiple initial charging parameters and the multiple actual charging parameters, a current maximum usable capacity of the battery; acquire, according to the current maximum usable capacity and the current number of charging times, a capacity correlation, where the capacity correlation includes a correspondence between the predicted battery capacity and the number of charging times; and acquiring, according to the capacity correlation, the predicted battery capacity of the battery in the next charging process.

In an embodiment, the battery capacity acquisition module is further configured to: acquire, according to the multiple initial charging parameters, an initial capacity increment profile; acquire, according to the multiple actual charging parameters, an actual capacity increment profile; and estimate, according to the initial capacity increment profile and the actual capacity increment profile, the current maximum usable capacity of the battery.

In an embodiment, the battery capacity acquisition module is further configured to: acquire first initial position information corresponding to a second initial peak value and second initial position information corresponding to a third initial peak value on the initial capacity increment profile; acquire first current position information corresponding to a second actual peak value and second current position information corresponding to a third actual peak value on the actual capacity increment profile; and estimate, according to the first initial position information, the second initial position information, the first current position information, the second current position information, the multiple initial charging parameters and the actual charging parameters, the current maximum usable capacity of the battery.

In an embodiment, the battery capacity acquisition module is further configured to: acquire a target number of charging times corresponding to the next charging process; acquire, according to the target number of charging times and the capacity correlation, the predicted battery capacity of the battery in the next charging process.

In an embodiment, the device further includes: a historical parameter acquisition module, configured to acquire a historical maximum usable capacity in historical charging processes before the current charging process and a historical number of charging times corresponding to the historical maximum usable capacity. The battery capacity acquisition module is further configured to: acquire, according to the current maximum usable capacity, the current number of charging times, the historical maximum usable capacity and the historical number of charging times, the capacity correlation.

In a third aspect, the present disclosure provides a non-transitory computer readable storage medium, on which a computer program is stored. The computer program, when executed by a processor, implements steps of the method for acquiring a battery capacity according to the present disclosure.

In a fourth aspect, the present disclosure provides a server, which includes a: a memory, and on which a computer program is stored; and a processor, configured to execute the computer program in the memory, to implement steps of the method for acquiring a battery capacity according to the present disclosure.

Through the above technical solutions, multiple initial charging parameters of a vehicle battery are acquired when a current charging process of the battery is effective charging, where the effective charging may mean that the range of variation in SOC of the battery in the current charging process covers a preset SOC range, and the minimum charging temperature of the battery in the current charging process is greater than or equal to a preset temperature threshold. Multiple actual charging parameters of the battery in the current charging process and a current number of effective charging times corresponding to the current charging process are periodically acquired. A predicted battery capacity of the battery in a next effective charging process is acquired according to the multiple initial charging parameters, the multiple actual charging parameters, and the current number of effective charging times. As such, the charging parameters of the battery can be acquired in an effective charging process of the battery with no need to stand still, to estimate a predicted battery capacity of the battery in a next effective charging process. Therefore, the efficiency of estimating the battery capacity is improved.

Other features and advantages of the present disclosure will be described in detail in the following detailed description.

### BRIEF DESCRIPTION OF THE DRAWINGS

The accompanying drawings provides further understanding of the present disclosure and constitute a part of this specification. The accompanying drawings, together with the following detailed description, serve to explain the present disclosure, and do not constitute a restriction on the present disclosure.

FIG. 1 is a flow chart of a method for acquiring a battery capacity according to an embodiment.

FIG. 2 is a flow chart of a method for acquiring a battery capacity according to another embodiment.

FIG. 3 is a schematic diagram showing an interval capacity integral value according to an embodiment.

FIG. 4 is a schematic diagram showing a maximum usable capacity according to an embodiment.

FIG. 5 is a schematic structural diagram of a device for acquiring a battery capacity according to an embodiment.

FIG. 6 is a schematic structural diagram of a device for acquiring a battery capacity according to another embodiment.

FIG. 7 is a block diagram of a server according to an embodiment.

### DETAILED DESCRIPTION

Implementations of the present disclosure are described in detail below with reference to the accompanying drawings. It should be understood that the implementations described herein are merely used to describe and explain the present disclosure, but not to limit the present disclosure.

In the description below, the words “first”, “second”, and others are merely used for the purpose of distinctive description, and cannot be interpreted as indicating or implying relative importance, or indicating or implying the sequence.

The application scenario of the present disclosure is described. The present disclosure is applicable to a scenario where the battery capacity is estimated. The battery capacity reflects a current health state of a battery. Due to the failure to achieve full charge and discharge under laboratory conditions, complex and changeable working conditions, aging of the battery, different battery material systems, and other factors in practical use, the estimation of battery capacity has become a great challenge and an important task.

In the related art, the OCV and the capacity of a battery can be obtained by a system identification algorithm base on a mathematical model of the battery. If the standing time of the battery pack exceeds a preset time, OCV is detected. In each time interval, the range of variation of the battery capacity is calculated, and the range of variation of the battery capacity is looked up according to OCV lookup table. The weight of the battery capacity attenuation is calculated according to the two variables of the range of variation of the battery capacity calculated above, and the current battery capacity is calculated according to the battery capacity at a previous moment and the weight. In this method, the estimation efficiency of the battery capacity is low, and the dependency on the sampling accuracy of the current, voltage, and temperature of the battery is high, causing a low estimation accuracy of the battery capacity.

To solve the above problems, the present disclosure provides a method and a device for acquiring a battery capacity, a storage medium and a server having the same. In a charging process of a vehicle, multiple actual charging parameters and a current number of effective charging times corresponding to the current charging process of a battery are acquired. According to multiple initial charging parameters, the multiple actual charging parameters, and the current number of effective charging times, a predicted battery capacity of the battery in a next effective or next charging process can be obtained. As such, the charging parameters of the battery can be acquired in an effective charging process of the battery with no need to stand still, to estimate a predicted battery capacity of the battery in a next effective charging process. Therefore, the efficiency of estimating the battery capacity is improved.

Implementations of the present disclosure are described in detail below with reference to the accompanying drawings.

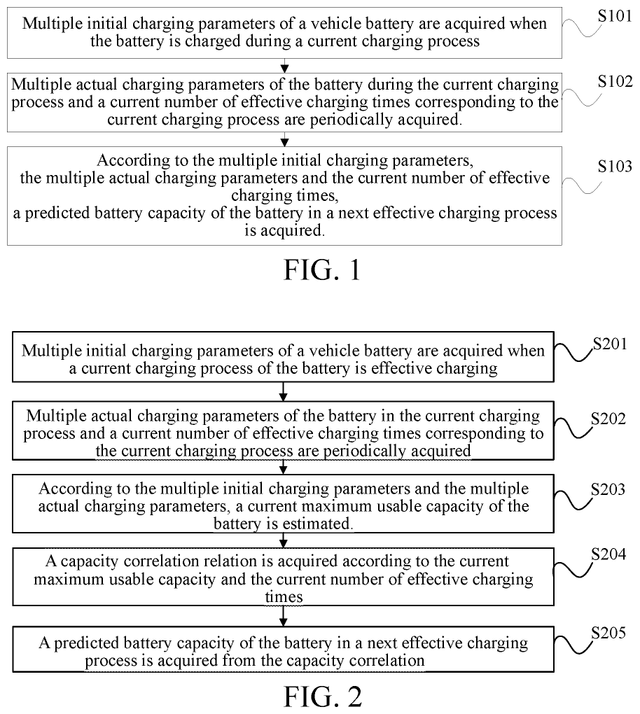

FIG. 1 is a flow chart of a method for acquiring a battery capacity according to an embodiment. As shown in FIG. 1, the method includes the followings.

S101: Multiple initial charging parameters of a vehicle battery are acquired when the battery is charged during a current charging process.

The battery may be a power battery pack, the effective charging process may mean that the range of variation in SOC of the battery in the current charging process covers a preset SOC range, and the minimum charging temperature of the battery in the current charging process is greater than or equal to a preset temperature threshold. The preset SOC range and the preset temperature threshold can be determined according to the material of the battery and actual working conditions during use. For example, a capacity increment profile of the battery may include three peaks, i.e. a first peak value, a second peak value, and a third peak value. According to the characteristics of power lithium ion batteries and the experimental data of practical applications, the first peak value usually appears in 0 to 20% SOC of the battery, and the second peak value and the third peak value usually appear in 20% to 90% SOC of the battery, during the charging process of the battery. The battery is generally charged when the SOC is more than 20% during the practical use. Based on this, in the present disclosure, a predicted battery capacity of the battery in a next effective charging process can be acquired according to position information of the second peak value and position information of the third peak value. Therefore, the preset SOC range can be set to a range including the second peak value and the third peak value, for example, 20% to 90%, and the preset temperature threshold may be 10° C., which are not limited in the present disclosure. If the range of variation in SOC of the battery is from 15% to 90% in the current charging process and the minimum charging temperature of the battery in the current charging process is 15° C., it may be determined that the current charging process is an effective charging process. If the range of variation in SOC of the battery is from 15% to 80% in the current charging process and the minimum charging temperature of the battery in the current charging process is 7° C., it may be determined that the current charging process is an ineffective charging process.

In this step, after the current charging process is completed, whether the current charging process is an effective charging process can be determined. If the current charging process is determined to be an effective charging process, multiple initial charging parameters of the battery are acquired. For example, after the current charging process is completed, the range of variation in SOC and the minimum charging temperature of the battery in the current charging process can be acquired. If it is determined that the range of variation in SOC includes the preset SOC range and the charging temperature of the battery is greater than or equal to the preset temperature threshold, multiple initial charging parameters of the battery are acquired. The multiple initial charging parameters can be pre-stored in a server.

It should be noted that the initial charging parameters may be standard charging parameters obtained during the full discharging and full charging process of the battery. After the full discharging and full charging of the battery, the battery capacity can reach a maximum capacity. However, in normal use, the charging process of the battery is difficult to meet the conditions of fully discharging and fully charging. Therefore, a current maximum usable capacity of the battery during normal use cannot reach the maximum capacity of the full discharging/charging process, and the current maximum usable capacity will be less than the maximum capacity. If a battery manager uses the maximum capacity as the current maximum available capacity, the accuracy of the current maximum usable capacity is low, which may cause the safety concern of the battery. Therefore, the predicted battery capacity of the battery needs to be acquired accurately. Here, the predicted battery capacity of the battery can be acquired according to the initial charging parameters and the actual charging parameters. The multiple initial charging parameters can be obtained by a battery experimental test platform in the fully discharging and full charging process of the battery. The fully discharging and full charging process includes the following.

S1: At room temperature, the battery is discharged with a constant current at a first rate until the voltage of each cell in the battery reaches a first cut-off voltage.

S2: The battery stands for a first preset period of time.

S3: At room temperature, the battery is charged with a constant current at a second rate until the voltage of each cell in the battery reaches a second cut-off voltage.

S4: The battery stands for a second preset period of time.

S5: At room temperature, the battery is charged with a constant current at a third rate until the voltage of each cell in the battery reaches the second cut-off voltage.

The first rate, the first cut-off voltage, the first preset period of time, the second rate, the second cut-off voltage, the second preset period of time and the third rate can be preset according to the battery core characteristics of the battery. For example, the first rate may be 0.3 C, the first cut-off voltage may be 2 V, the first preset period of time may be 1800s, the second rate may be 1 C, the second cut-off voltage may be 3.75 V, the second preset period of time may be 300s, and the third rate may be 0.2 C.

After the battery enters the full discharging and full charging process, that is, after the battery starts to discharge with a constant current at the first rate, the initial charging parameters of the battery can be collected periodically, where the collection interval can be determined according to the performance of a sampling circuit. For example, the better the performance of the sampling circuit is, the shorter the sampling interval will be, such as, 50 ms; and the worse the performance of the sampling circuit is, the longer the sampling interval will be, such as, 100 ms, which are not limited in the present disclosure. After the battery is charged with a constant current at the third rate until the voltage of each cell in the battery reaches the second cut-off voltage, the collection of the initial charging parameters is stopped. Then, the initial charging parameters collected in the fully discharging and full charging process are stored in a server.

It should be noted that, in the present disclosure, whether the current charging process is an effective charging process can also be determined in the current charging process of the battery. For example, the initial SOC of the battery and the charging temperature of the battery can be obtained at the beginning of the current charging process. Then, in the current charging process, the current SOC of the battery and the charging temperature of the battery can be obtained periodically. If the ranges covered by the initial SOC and the current SOC include the preset SOC range, and the minimum charging temperature of the battery is less than the preset temperature threshold, the current charging process is an effective charging process, and multiple initial charging parameters of the battery can be acquired, For example, if the preset SOC range is from 20% to 90% and the initial SOC of the battery acquired at the beginning of the current charging process is 15%, the current SOC of the battery can be obtained periodically in the current charging process. If it is determined that the current SOC reaches 90% and the minimum charging temperature of the battery in the process is less than or equal to the preset temperature threshold, the current charging process can be determined to be an effective charging process. As such, before the current charging process is completed, the current charging process is determined to be an effective charging process, and initial charging parameters of the battery are acquired. Therefore, the efficiency of estimating the battery capacity is improved.

S102: Multiple actual charging parameters of the battery during the current charging process and a current number of effective charging times corresponding to the current charging process are periodically acquired.

In this step, after the current charging process is started, the actual charging parameters of the battery are periodically acquired, where the method for setting the acquisition interval can be referred to the collection period of the initial charging parameters, and details will not be repeated here. In addition, if the current charging process is determined to be an effective charging process, a current number of effective charging times corresponding to the current charging process can be determined. The current number of effective charging times can be determined according to a historical number of effective charging times. For example, the current number of effective charging times may be the historical number of effective charging times plus 1. For example, if the historical number of effective charging times is 10, the current number of effective charging times is 11. In addition, after each completion of effective charging of the battery, the historical number of effective charging times is increased by 1. For example, after the first process of effective charging is completed, the historical number of effective charging times is 1; and after the second process of effective charging is completed, the historical number of effective charging times is 2.

S103: According to the multiple initial charging parameters, the multiple actual charging parameters, and the current number of effective charging times, a predicted battery capacity of the battery in a next effective charging process is acquired.

In this step, after acquiring the multiple initial charging parameters, the multiple actual charging parameters, and the current number of effective charging times, a target number of charging times corresponding to the next effective charging process can be determined according to the historical number of effective charging times. Then, according to the multiple initial charging parameters, the multiple actual charging parameters, the current number of effective charging times, and the target number of charging times, the predicted battery capacity of the battery in the next effective charging process is acquired.

By the method above, the predicted battery capacity of the battery in the next effective charging process can be acquired according to the multiple initial charging parameters, the multiple actual charging parameters, and the current number of effective charging times. As such, the charging parameters of the battery can be acquired in an effective charging process of the battery with no need to stand still, to estimate a predicted battery capacity of the battery in a next effective charging process. Therefore, the efficiency of estimating the battery capacity is improved.

FIG. 2 is a flow chart of a method for acquiring a battery capacity according to another embodiment. As shown in FIG. 2, the method includes:

S201: Multiple initial charging parameters of a vehicle battery are acquired when a current charging process of the battery is effective charging.

The battery may be a power battery pack, the effective charging process may mean that the range of variation in SOC of the battery in the current charging process covers a preset SOC range, and the minimum charging temperature of the battery in the current charging process is greater than or equal to a preset temperature threshold. The preset SOC range and the preset temperature threshold can be determined according to the material of the battery, and actual working conditions during use. For example, three peak values, i.e. a first peak value, a second peak value and a third peak value, are present in SOC range of the battery. A predicted battery capacity of the battery in a next effective charging process can be acquired according to position information of the second peak value and position information of the third peak value in the present disclosure. Therefore, the preset SOC range can be set to a range including the second peak value and third peak value, for example, 20% to 90%; and the preset temperature threshold may be 10° C., which are not limited in the present disclosure. If the range of variation in SOC of the battery is from 15% to 90% in the current charging process and the minimum charging temperature of the battery in the current charging process is 15° C., it may be determined that the current charging process is an effective charging process. If the range of variation in SOC of the battery is from 15% to 80% in the current charging process and the minimum charging temperature of the battery in the current charging process is 7° C., it may be determined that the current charging process is ineffective charging. In addition, the initial charging parameters can include an initial charging voltage and an initial charging current.

S202: Multiple actual charging parameters of the battery in the current charging process and a current number of effective charging times corresponding to the current charging process are periodically acquired.

The actual charging parameters can include an actual charging voltage and an actual charging current.

S203: According to the multiple initial charging parameters and the multiple actual charging parameters, a current maximum usable capacity of the battery is estimated.

In this step, after the multiple initial charging parameters and the multiple actual charging parameters are acquired, an initial capacity increment profile is acquired according to the initial charging parameters; an actual capacity increment profile is acquired according to the actual charging parameters; and a current maximum usable capacity of the battery is estimated according to the initial capacity increment profile and the actual capacity increment profile.

The initial capacity increment profile can be acquired through the following steps.

S1: A preset voltage interval is acquired.

The preset voltage interval may be preset. For example, the preset voltage interval is 5 mV, or 20 mV, which is not limited in the present disclosure.

S2: Multiple initial capacity increment values are acquired according to multiple initial charging currents and multiple initial charging voltages in the multiple initial charging parameters.

The capacity increment value is a capacity value corresponding to unit voltage increment. For example, the initial capacity increment value can be calculated by a formula below:

$${IC}_{i} = \frac{{I}_{i}}{{dV}_{i} / dt} \qquad ( 1 )$$

where ICᵢ is an i^{th} initial capacity increment value, Iᵢ is an i^{th} initial charging current, and Vᵢ is an initial charging voltage.

S3: The initial capacity increment profile is generated according to the preset voltage interval and the multiple capacity increment values.

After the preset voltage interval and the multiple initial capacity increment values are acquired, the initial capacity increment profile is generated with the voltage as the horizontal axis and the capacity increment value as the vertical axis according to the preset voltage interval.

It should be noted that after the initial capacity increment profile is acquired, the actual capacity increment profile can be acquired through a method as described for the initial capacity increment profile, which will not be described here again.

After the initial capacity increment profile and the actual capacity increment profile are acquired, first initial position information corresponding to a second initial peak value and second initial position information corresponding to a third initial peak value on the initial capacity increment profile are acquired; first current position information corresponding to a second actual peak value and second current position information corresponding to a third actual peak value on the actual capacity increment profile are acquired; and the current maximum usable capacity of the battery is estimated according to the first initial position information, the second initial position information, the first current position information, the second current position information, the initial charging parameters, and the actual charging parameters.

After the first initial position information and the second initial position information are acquired, an initial interval capacity integral value is acquired according to the initial capacity increment profile, the first initial position information and the second initial position information. The initial interval capacity integral value is the capacity integral value between two peaks in the time interval between the second initial peak value and the third initial peak value. For example, the initial interval capacity integral value is acquired by a formula below:

$${Q}_{c} = {\int }_{{t}_{II}}^{{t}_{III}} {I}_{i} dt \qquad ( 2 )$$

where Q_{c} is the initial interval capacity integral value, t_{II} is the first initial position information of the second initial peak value, t_{III} the second initial position information of the third initial peak value, and Iᵢ is an i^{th} initial charging current.

It should be noted that after the initial capacity increment profile and the actual capacity increment profile are acquired, noises in the initial capacity increment profile and the actual capacity increment profile can be filtered off by preprocessing the initial capacity increment profile and the actual capacity increment profile by methods including a means algorithm, low-pass filtering, and others. Therefore, a more precise initial capacity increment profile and actual capacity increment profile are obtained, so that the predicted battery capacity estimated according to the initial capacity increment profile and the actual capacity increment profile is more accurate.

In addition to the acquisition of the initial interval capacity integral value according to the position information of the second peak value and the third peak value of the initial capacity increment profile, the initial interval capacity integral value can also be calculated according to the area corresponding to a region between the second initial peak value and the third initial peak value, the slopes corresponding to the second initial peak value and the third initial peak value, and others, which is not limited in the present disclosure.

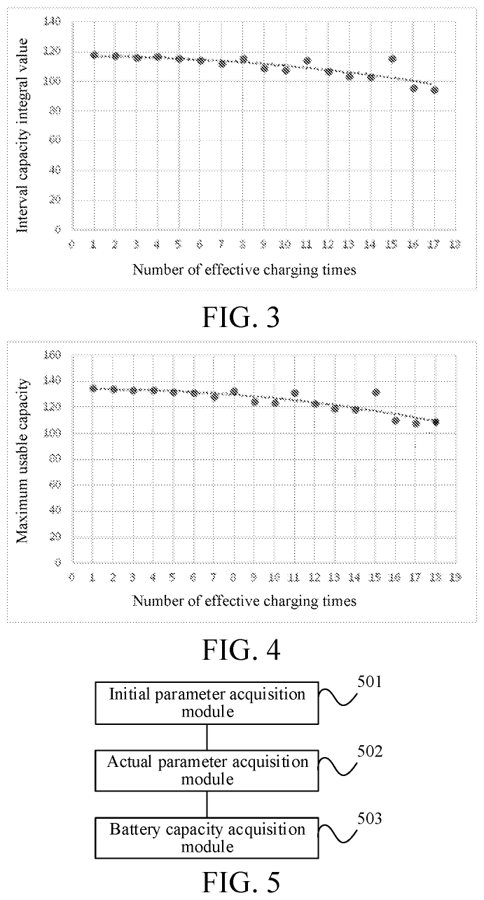

After the first current position information and the second current position information are acquired, an actual interval capacity integral value Qₛ can be acquired according to the actual charging parameters, the first current position information and the second current position information. The method for acquiring the actual interval capacity integral value can be referred to the method for acquiring the initial interval capacity integral value, which will not be described here again. FIG. 3 is a schematic diagram showing an interval capacity integral value according to an embodiment, in which the horizontal axis is the number of effective charging times, and the vertical axis is the interval capacity integral value. As shown in FIG. 3, with increasing number of effective charging times, the interval capacity integral value becomes increasingly smaller, indicating an increasing battery loss.

Further, after obtaining the initial interval capacity integral value and the actual interval capacity integral value, the current maximum usable capacity of the battery can be calculated by a formula below:

$${Q}_{max\_j} = \frac{{Q}_{s}}{{Q}_{c}} \cdot C \qquad ( 3 )$$

where Q_{max_j} is the current maximum usable capacity, j is the current number of effective charging times, Q_{c} is the initial interval capacity integral value, Qₛ is the actual interval capacity integral value, and C is an initial maximum usable capacity.

The initial maximum usable capacity can be calculated by a formula below:

$$C = {\int }_{t 1}^{t 2} {I}_{i} dt \qquad ( 4 )$$

where C is the initial maximum usable capacity, t1 is a start sampling time corresponding to the initial charging parameters, t2 is an end sampling time corresponding to the initial charging parameters, and Iᵢ is an i^{th} initial charging current.

FIG. 4 is a schematic diagram showing a maximum usable capacity according to an embodiment, where the horizontal axis is the number of effective charging times, and the vertical axis is the maximum usable capacity. As shown in FIG. 4, with increasing number of effective charging times, the maximum usable capacity of the battery becomes increasingly smaller, indicating an increasing battery loss.

S204: A capacity correlation is acquired according to the current maximum usable capacity and the current number of effective charging times.

The capacity correlation includes a correspondence between the predicted battery capacity and the number of effective charging times.

In this step, after the current maximum usable capacity and the current number of effective charging times are acquired, the capacity correlation is acquired according to the current maximum usable capacity and the current number of effective charging times:

$${Q}_{max\_j} = \frac{{Q}_{s}}{{Q}_{c}} \cdot C = \frac{f ( {X}_{charge} )}{{Q}_{c}} \cdot C = g ( {X}_{charge} ) \qquad ( 5 )$$

where Q_{max_j} is the predicted battery capacity in case of effective charging, and X_{charge} is the number of effective charging times.

Through the conversion by Formula (5), the correspondence Q_{max_j}=g(X_{charge}) between the predicted battery capacity and the effective number of effective charging times can be obtained. To improve the accuracy of the predicted battery capacity, after the current maximum usable capacity is acquired, the capacity correlation can be obtained by fitting the current maximum usable capacity, the current number of effective charging times, a historical maximum usable capacity in all effective charging processes before the current charging process, and a historical number of effective charging times.

In an implementation, before the capacity correlation is acquired according to the current maximum usable capacity and the current number of effective charging times, the historical maximum usable capacity in all effective charging processes before the current charging process and the historical number of effective charging times corresponding to the historical maximum usable capacity are acquired. The capacity correlation is acquired according to the current maximum usable capacity, the current number of effective charging times, the historical maximum usable capacity and the historical number of effective charging times.

The method for calculating the historical maximum usable capacity can be referred to the method for calculating the current maximum usable capacity, which will not be described here again. After obtaining the current maximum usable capacity, the current number of effective charging times, the historical maximum usable capacity and the historical number of effective charging times, the capacity correlation can be obtained by fitting, including exponential fitting, linear fitting, logarithmic fitting, polynomial fitting, and power function fitting, etc., which is not limited in the present disclosure. Here, the fitting method can be referred to the implementation of related technologies, which will not be described here again.

For example, the capacity correlation obtained by fitting can be Formula (6) or Formula (7):

y=−0.0853x²+0.1721x+133.87 (6)

y=140.13e^{-0.012x} (7)

where y is the predicted battery capacity, and x is the number of effective charging times.

It should be noted that the capacity correlation expressed by Formula (6) and Formula (7) is merely exemplary (an expression obtained from experimental data), and different capacity correlations can be obtained by different fitting methods for different batteries, in different use environments, which are not limited in the present disclosure.

S205: A predicted battery capacity of the battery in a next effective charging process is acquired from the capacity correlation.

In this step, after the capacity correlation is acquired, a target number of charging times corresponding to the next effective charging process is acquired; and the predicted battery capacity of the battery in the next effective charging process is acquired according to the target number of charging times and the capacity correlation. For example, the predicted battery capacity can be calculated by introducing the target number of charging times into Formula (6) or (7). For example, if the target number of charging times is 10, the predicted battery capacity is calculated to be 144.121 by Formula (6).

By the method above, the capacity correlation can be acquired according to the current maximum usable capacity, the current number of effective charging times, the historical maximum usable capacity, and the historical number of effective charging times; and the predicted battery capacity of the battery in the next effective charging process is acquired from the capacity correlation. As such, the predicted battery capacity is obtained merely through calculation of the capacity correlation. Therefore, the efficiency of estimating the battery capacity is improved. In addition, the capacity correlation is acquired based on the charging parameters in the process of full discharging and full charging and historically accumulated parameters of all effective charging processes, so the accuracy of the capacity correlation is higher. Therefore, the predicted battery capacity obtained according to the capacity correlation has a higher accuracy.

FIG. 5 is a schematic structural diagram of a device for acquiring a battery capacity according to an embodiment. As shown in FIG. 5, the device includes:

an initial parameter acquisition module 501, configured to acquire multiple initial charging parameters of a battery when the battery is charged during a current charging process, where state of charge (SOC) of the battery in the current charging process changes for a range covering an SOC range, or a minimum charging temperature of the battery in the current charging process is greater than or equal to a temperature threshold;

an actual parameter acquisition module 502, configured to periodically acquire multiple actual charging parameters of the battery during the current charging process and a current number of effective charging times corresponding to the current charging process; and

a battery capacity acquisition module 503, configured to acquire, according to the multiple initial charging parameters, the multiple actual charging parameters and the current number of effective charging times, a predicted battery capacity of the battery in a next effective charging process.

In an embodiment, the battery capacity acquisition module 503 is further configured to: estimate a current maximum usable capacity of the battery according to the multiple initial charging parameters and the multiple actual charging parameters; acquire a capacity correlation according to the current maximum usable capacity and the current number of effective charging times, where the capacity correlation includes a correspondence between the predicted battery capacity and the number of effective charging times; and acquire the predicted battery capacity of the battery in the next effective charging process from the capacity correlation.

In an embodiment, the battery capacity acquisition module 503 is further configured to: acquire an initial capacity increment profile according to the initial charging parameters; acquire an actual capacity increment profile according to the actual charging parameters; and estimate the current maximum usable capacity of the battery according to the initial capacity increment profile and the actual capacity increment profile.

In an embodiment, the battery capacity acquisition module 503 is further configured to: acquire first initial position information corresponding to a second initial peak value and second initial position information corresponding to a third initial peak value on the initial capacity increment profile; acquire first current position information corresponding to a second actual peak value and second current position information corresponding to a third actual peak value on the actual capacity increment profile; and estimate the current maximum usable capacity of the battery according to the first initial position information, the second initial position information, the first current position information, the second current position information, the initial charging parameters and the actual charging parameters.

In an embodiment, the battery capacity acquisition module 503 is further configured to: acquire a target number of charging times corresponding to the next effective charging process; and acquire, according to the target number of charging times and the capacity correlation, the predicted battery capacity of the battery in the next effective charging process from the capacity correlation.

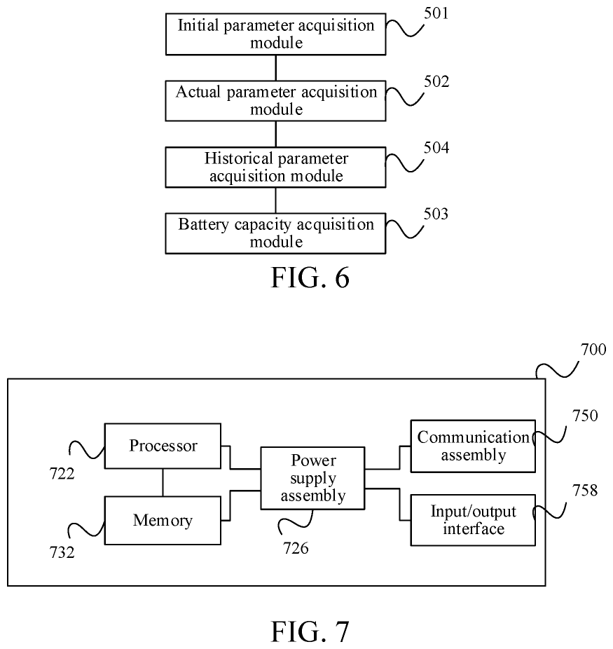

FIG. 6 is a schematic structural diagram of a device for acquiring a battery capacity according to another embodiment. As shown in FIG. 6, the device further includes:

a historical parameter acquisition module 504, configured to acquire a historical maximum usable capacity in all effective charging processes before the current charging process and a historical number of effective charging times corresponding to the historical maximum usable capacity.

The battery capacity acquisition module 503 is further configured to: acquire the capacity correlation according to the current maximum usable capacity, the current number of effective charging times, the historical maximum usable capacity and the historical number of effective charging times.

By using the device, the predicted battery capacity of the battery in the next effective charging process can be obtained according to the multiple initial charging parameters, the multiple actual charging parameters, and the current number of effective charging times. As such, the charging parameters of the battery can be acquired in an effective charging process of the battery with no need to stand still, to estimate a predicted battery capacity of the battery in a next effective charging process. Therefore, the efficiency of estimating the battery capacity is improved.

For the device in the embodiments above, each module performs an operation is already described in detail in the method embodiments, and details are not described herein again.

FIG. 7 is a block diagram of a server according to an embodiment. For example, referring to FIG. 7, the server may include the server 700, which includes one or more processors 722, and a memory 732 configured to store a computer program executable by the processor 722. The computer program stored in the memory 732 can include one or more sets of instructions. Moreover, the processor 722 can be configured to execute the computer program to perform the method for acquiring a battery capacity.

In addition, the server 700 may further include a power supply assembly 726 and a communication assembly 750. The power supply assembly 726 can be configured to perform power management on the server 700, and the communication assembly 750 can be configured to implement the communication of the server 700, for example, wired or wireless communication. Moreover, the server 700 may further include an input/output (I/O) interface 758. The server 700 may operate an operating system stored in the memory 732, such as Windows Server™, Mac OS X™, Unix™, and Linux™.

In another embodiment, a non-transitory computer-readable storage medium storing a program instruction is further provided. The program instruction, when executed by a processor, implements steps of the method for acquiring a battery capacity. For example, the non-transitory computer-readable storage medium may be the memory 732 storing the program instruction. The program instruction is executed by the process 722 of the server 700 to implement the method for acquiring a battery capacity.

In another embodiment, a computer program product is further provided, which includes a computer program executable by a programmable device. The computer program has codes that implements, when executed by the programmable device, the method for acquiring a battery capacity.

Some embodiments of the present disclosure have been described in detail above with reference to the accompanying drawings. However, the present disclosure is not limited to the details in the foregoing embodiments. Within the scope of the technical concept of the present disclosure, a variety of simple modifications can be made to the technical solution of the present disclosure, which fall within the protection scope of the present disclosure. In addition, it should be noted that the various technical features described in the foregoing embodiments can be combined in any suitable manner, where there is no contradiction. In order to avoid unnecessary repetition, various possible combinations are not described separately in the present disclosure.

Moreover, different embodiments of the present disclosure can also be arbitrarily combined without departing from the idea of the present disclosure, and these combinations shall still be regarded as content disclosed in the present disclosure.

What is claimed is:

1. A method for acquiring a battery capacity, comprising:
acquiring multiple initial charging parameters of a battery when the battery is charged during a current charging process, wherein state of charge (SOC) of the battery in the current charging process changes for a range covering an SOC range, or a minimum charging temperature of the battery in the current charging process is greater than or equal to a temperature threshold;
periodically acquiring multiple actual charging parameters of the battery during the current charging process and a current number of charging times corresponding to the current charging process; and
acquiring, according to the multiple initial charging parameters, the multiple actual charging parameters, and the current number of charging times, a predicted battery capacity of the battery in a next charging process.

2. The method according to claim 1, wherein the acquiring, according to the multiple initial charging parameters, the multiple actual charging parameters, and the current number of charging times, a predicted battery capacity of the battery in a next charging process comprises:
estimating, according to the multiple initial charging parameters and the multiple actual charging parameters, a current maximum usable capacity of the battery;
acquiring, according to the current maximum usable capacity and the current number of charging times, a capacity correlation, wherein the capacity correlation comprises a correspondence between the predicted battery capacity and the current number of charging times; and
acquiring, according to the capacity correlation, the predicted battery capacity of the battery in the next charging process.

3. The method according to claim 2, wherein the estimating, according to the multiple initial charging parameters and the multiple actual charging parameters, a current maximum usable capacity of the battery comprises:
acquiring, according to the multiple initial charging parameters, an initial capacity increment profile;
acquiring, according to the multiple actual charging parameters, an actual capacity increment profile; and
estimating, according to the initial capacity increment profile and the actual capacity increment profile, the current maximum usable capacity of the battery.

4. The method according to claim 3,
wherein the estimating, according to the initial capacity increment profile and the actual capacity increment profile, the current maximum usable capacity of the battery comprises:
acquiring first initial position information corresponding to a second initial peak value and second initial position information corresponding to a third initial peak value on the initial capacity increment profile;
acquiring first current position information corresponding to a second actual peak value and second current position information corresponding to a third actual peak value on the actual capacity increment profile; and
estimating, according to the first initial position information, the second initial position information, the first current position information, the second current position information, the multiple initial charging parameters, and the multiple actual charging parameters, the current maximum usable capacity of the battery.

5. The method according to claim 2, wherein the acquiring, according to the capacity correlation, the predicted battery capacity of the battery in the next charging process comprises:
acquiring a target number of charging times corresponding to the next charging process; and
acquiring, according to the target number of charging times and the capacity correlation, the predicted battery capacity of the battery in the next charging process.

6. The method according to claim 2, further comprising, before the acquiring, according to the current maximum usable capacity and the current number of charging times, a capacity correlation,
acquiring a historical maximum usable capacity in historical charging processes before the current charging process and a historical number of charging times corresponding to the historical maximum usable capacity; and
the acquiring, according to the current maximum usable capacity and the current number of charging times, a capacity correlation comprises:
acquiring, according to the current maximum usable capacity, the current number of charging times, the historical maximum usable capacity and the historical number of charging times, the capacity correlation.

7. The method according to claim 4, wherein the second peak value and the third peak value are within the SOC range.

8. A device for acquiring a battery capacity, comprising a memory storing a computer program, and a processor configured to execute the computer program and perform operations comprising:
acquiring multiple initial charging parameters of a battery when the battery is charged during a current charging process, wherein state of charge (SOC) of the battery in the current charging process changes for a range covering an SOC range, or a minimum charging temperature of the battery in the current charging process is greater than or equal to a temperature threshold;
periodically acquiring multiple actual charging parameters of the battery during the current charging process and a current number of charging times corresponding to the current charging process; and
acquiring, according to the multiple initial charging parameters, the multiple actual charging parameters, and the current number of charging times, a predicted battery capacity of the battery in a next charging process.

9. The device according to claim 8, wherein the acquiring, according to the multiple initial charging parameters, the multiple actual charging parameters, and the current number of charging times, a predicted battery capacity of the battery in a next charging process comprises:
estimating, according to the multiple initial charging parameters and the multiple actual charging parameters, a current maximum usable capacity of the battery;
acquiring, according to the current maximum usable capacity and the current number of charging times, a capacity correlation, wherein the capacity correlation comprises a correspondence between the predicted battery capacity and the current number of charging times; and
acquiring, according to the capacity correlation, the predicted battery capacity of the battery in the next charging process.

10. The device according to claim 9, wherein the estimating, according to the multiple initial charging parameters and the multiple actual charging parameters, a current maximum usable capacity of the battery comprises:
acquiring, according to the multiple initial charging parameters, an initial capacity increment profile;
acquiring, according to the multiple actual charging parameters, an actual capacity increment profile; and
estimating, according to the initial capacity increment profile and the actual capacity increment profile, the current maximum usable capacity of the battery.

11. The device according to claim 10,
wherein the estimating, according to the initial capacity increment profile and the actual capacity increment profile, the current maximum usable capacity of the battery comprises:
acquiring first initial position information corresponding to a second initial peak value and second initial position information corresponding to a third initial peak value on the initial capacity increment profile;
acquiring first current position information corresponding to a second actual peak value and second current position information corresponding to a third actual peak value on the actual capacity increment profile; and
estimating, according to the first initial position information, the second initial position information, the first current position information, the second current position information, the multiple initial charging parameters, and the multiple actual charging parameters, the current maximum usable capacity of the battery.

12. The device according to claim 9, wherein the acquiring, according to the capacity correlation, the predicted battery capacity of the battery in the next charging process comprises:
acquiring a target number of charging times corresponding to the next charging process; and
acquiring, according to the target number of charging times and the capacity correlation, the predicted battery capacity of the battery in the next charging process.

13. The device according to claim 9, wherein before the acquiring, according to the current maximum usable capacity and the current number of charging times, a capacity correlation, the operations further comprise:
acquiring a historical maximum usable capacity in historical charging processes before the current charging process and a historical number of charging times corresponding to the historical maximum usable capacity; and
the acquiring, according to the current maximum usable capacity and the current number of charging times, a capacity correlation comprises:
acquiring, according to the current maximum usable capacity, the current number of charging times, the historical maximum usable capacity and the historical number of charging times, the capacity correlation.

14. Anon-transitory computer readable storage medium, storing a computer program, wherein the computer program, when executed by a processor, performs operations comprising:
acquiring multiple initial charging parameters of a battery when the battery is charged during a current charging process, wherein state of charge (SOC) of the battery in the current charging process changes for a range covering an SOC range, or a minimum charging temperature of the battery in the current charging process is greater than or equal to a temperature threshold;
periodically acquiring multiple actual charging parameters of the battery during the current charging process and a current number of charging times corresponding to the current charging process; and
acquiring, according to the multiple initial charging parameters, the multiple actual charging parameters, and the current number of charging times, a predicted battery capacity of the battery in a next charging process.

15. The non-transitory computer readable storage medium according to claim 14, wherein the acquiring, according to the multiple initial charging parameters, the multiple actual charging parameters, and the current number of charging times, a predicted battery capacity of the battery in a next charging process comprises:
estimating, according to the multiple initial charging parameters and the multiple actual charging parameters, a current maximum usable capacity of the battery;
acquiring, according to the current maximum usable capacity and the current number of charging times, a capacity correlation, wherein the capacity correlation comprises a correspondence between the predicted battery capacity and the current number of charging times; and
acquiring, according to the capacity correlation, the predicted battery capacity of the battery in the next charging process.

16. The non-transitory computer readable storage medium according to claim 15, wherein the estimating, according to the multiple initial charging parameters and the multiple actual charging parameters, a current maximum usable capacity of the battery comprises:
acquiring, according to the multiple initial charging parameters, an initial capacity increment profile;
acquiring, according to the multiple actual charging parameters, an actual capacity increment profile; and
estimating, according to the initial capacity increment profile and the actual capacity increment profile, the current maximum usable capacity of the battery.

17. The non-transitory computer readable storage medium according to claim 16, wherein the estimating, according to the initial capacity increment profile and the actual capacity increment profile, the current maximum usable capacity of the battery comprises:
acquiring first initial position information corresponding to a second initial peak value and second initial position information corresponding to a third initial peak value on the initial capacity increment profile;
acquiring first current position information corresponding to a second actual peak value and second current position information corresponding to a third actual peak value on the actual capacity increment profile; and
estimating, according to the first initial position information, the second initial position information, the first current position information, the second current position information, the multiple initial charging parameters, and the multiple actual charging parameters, the current maximum usable capacity of the battery.

18. The non-transitory computer readable storage medium according to claim 15, wherein the acquiring, according to the capacity correlation, the predicted battery capacity of the battery in the next charging process comprises:
acquiring a target number of charging times corresponding to the next charging process; and
acquiring, according to the target number of charging times and the capacity correlation, the predicted battery capacity of the battery in the next charging process.

19. The non-transitory computer readable storage medium according to claim 15, wherein before the acquiring, according to the current maximum usable capacity and the current number of charging times, a capacity correlation, the operations further comprise:
acquiring a historical maximum usable capacity in historical charging processes before the current charging process and a historical number of charging times corresponding to the historical maximum usable capacity; and
the acquiring, according to the current maximum usable capacity and the current number of charging times, a capacity correlation r comprises:
acquiring, according to the current maximum usable capacity, the current number of charging times, the historical maximum usable capacity and the historical number of charging times, the capacity correlation.

20. A server, comprising:
a memory, storing a computer program; and
a processor, configured to execute the computer program in the memory, to implement the method according to claim 1.
